(19) United States
(12) Patent Application Publication
(10) Pub. No.: US 2026/0150643 A1
(43) Pub. Date: May 28, 2026

(54) SEMICONDUCTOR DEVICE AND FABRICATING METHOD THEREOF

(71) Applicant: TAIWAN SEMICONDUCTOR MANUFACTURING COMPANY, LTD., Hsinchu (TW)

(72) Inventors: Cheng-Yin WANG, Taipei City (TW); Jui-Chien HUANG, Hsinchu City (TW); Ting-Yun WU, Taipei City (TW); Meng-Yu LIN, New Taipei City (TW); Lu YANG, Hsinchu City (TW); Szuya LIAO, Hsinchu County (TW)

(73) Assignee: TAIWAN SEMICONDUCTOR MANUFACTURING COMPANY, LTD., Hsinchu (TW)

(21) Appl. No.: 18/962,580

(22) Filed: Nov. 27, 2024

(51) Int. Cl. H01L 23/522; H01L 23/528; H10B 10/00

(52) U.S. Cl. CPC H10W 20/42; H10B 10/12; H10W 20/435

(57) ABSTRACT

A device includes a first source/drain structure, a second source/drain structure, a first conductive segment, a second conductive segment, a first via structure and a second via structure. The second source/drain structure is disposed above the first source/drain structure along a first direction. The first conductive segment is disposed below the first source/drain structure along the first direction. The second conductive segment is disposed above the second source/drain structure along the first direction. The first via structure is coupled to the first conductive segment, and configured to transmit a first reference voltage signal from a first side through the first conductive segment to the first source/drain structure. The second via structure is coupled to the second conductive segment, and configured to transmit a second reference voltage signal from the first side through the second conductive segment to the second source/drain structure.

### BACKGROUND

Traditional 6-transistors (6T) static random-access memory (SRAM) at current industry is standing on 8-transistors (8T) footprint with within cell interconnection occupying the 2-transistors (2T) footprint that is not used by transistors on 6T SRAM. With current cutting edge CFET design, the 6T SRAM footprint can be shrink down to 4-transistors (4T). However, the signal and power will share the same routing resource on both side will increase the complexity of circuit design.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a circuit diagram of a semiconductor device, illustrated in accordance with some embodiments of the present disclosure.

FIG. 2A is a layout diagram of a semiconductor device corresponding to the semiconductor device shown in FIG. 1, illustrated in accordance with some embodiments of the present disclosure.

FIG. 2B is a layout diagram of further details of the semiconductor device shown in FIG. 2A, illustrated in accordance with some embodiments of the present disclosure.

FIG. 2C is a layout diagram of further details of the semiconductor device shown in FIG. 2A, illustrated in accordance with some embodiments of the present disclosure.

FIG. 2D is a cross sectional diagram along a line of the semiconductor device shown in FIG. 2A, illustrated in accordance with some embodiments of the present disclosure.

FIG. 2E is a cross sectional diagram along a line of the semiconductor device shown in FIG. 2A, illustrated in accordance with some embodiments of the present disclosure.

FIG. 2F is a cross sectional diagram along a line of the semiconductor device shown in FIG. 2A, illustrated in accordance with some embodiments of the present disclosure.

FIG. 3A is a circuit diagram of a semiconductor device corresponding to the semiconductor device 100 shown in FIG. 1, illustrated in accordance with some embodiments of the present disclosure.

FIG. 3B is a circuit diagram of a semiconductor device corresponding to the semiconductor device shown in FIG. 2A, illustrated in accordance with some embodiments of the present disclosure.

FIG. 3C is a flowchart diagram of a method for fabricating the semiconductor devices described above, illustrated in accordance with some embodiments of the present disclosure.

FIG. 4 is a schematic view of a system for designing and manufacturing at least one of the semiconductor devices described above, illustrated in accordance with some embodiments of the present disclosure.

FIG. 5 is a block diagram of an integrated circuit (IC)/semiconductor device manufacturing system, and an IC manufacturing flow associated therewith, illustrated in accordance with some embodiments of the present disclosure.

### DETAILED DESCRIPTION

The following disclosure provides many different embodiments, or examples, for implementing different features of the provided subject matter. Specific examples of components, materials, values, steps, arrangements or the like are described below to simplify the present disclosure. These are, of course, merely examples and are not intended to be limiting. Other components, materials, values, steps, arrangements or the like are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The terms applied throughout the following descriptions and claims generally have their ordinary meanings clearly established in the art or in the specific context where each term is used. Those of ordinary skill in the art will appreciate that a component or process may be referred to by different names. Numerous different embodiments detailed in this specification are illustrative only, and in no way limits the scope and spirit of the disclosure or of any exemplified term.

It is worth noting that the terms such as “first” and “second” used herein to describe various elements or processes aim to distinguish one element or process from another. However, the elements, processes and the sequences thereof should not be limited by these terms. For example, a first element could be termed as a second element, and a second element could be similarly termed as a first element without departing from the scope of the present disclosure.

In the following discussion and in the claims, the terms “comprising,” “including,” “containing,” “having,” “involving,” and the like are to be understood to be open-ended, that is, to be construed as including but not limited to. As used herein, instead of being mutually exclusive, the term “and/or” includes any of the associated listed items and all combinations of one or more of the associated listed items.

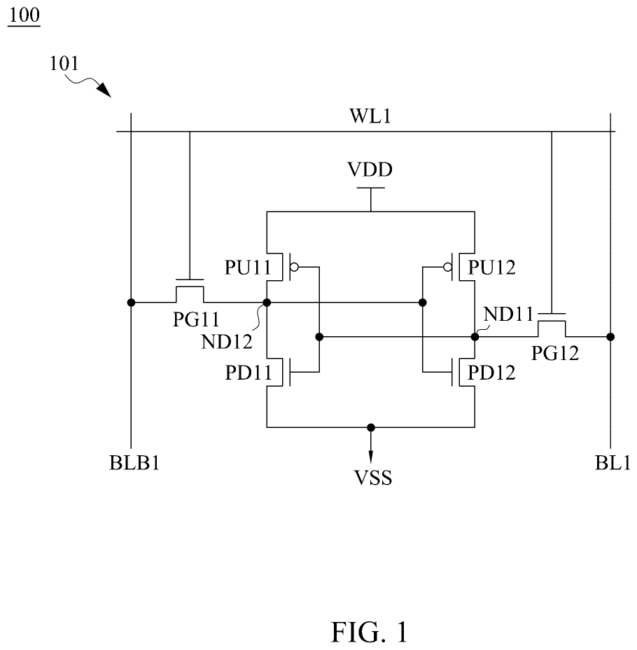

FIG. 1 is a circuit diagram of a semiconductor device 100, illustrated in accordance with some embodiments of the present disclosure. In some embodiments, the semiconductor device 100 includes multiple memory cells, such as a memory cell 101 shown in FIG. 1. In some embodiments, the semiconductor device 100 is referred to as a static random-access memory (SRAM) device.

As illustratively shown in FIG. 1, the memory cell 101 includes switches PG11, PG12, PU11, PU12, PD11 and PD12. Each of control terminals of the switches PG11 and PG12 is configured to receive a word line signal WL1. A terminal of the switch PG11 is configured to receive a bit line signal BLB1, and another terminal of the switch PG11 is coupled to a node ND12. A terminal of the switch PG12 is configured to receive a bit line signal BL1, and another terminal of the switch PG12 is coupled to a node ND11. Each of control terminals of the switches PU11 and PD11 is coupled to the node ND11. A terminal of the switch PU11 is configured to receive a reference voltage signal VDD, another terminal of the switch PU11 is coupled to the node ND12. A terminal of the switch PD11 is configured to receive a reference voltage signal VSS, another terminal of the switch PU11 is coupled to the node ND12. Each of control terminals of the switches PU12 and PD12 is coupled to the node ND12. A terminal of the switch PU12 is configured to receive the reference voltage signal VDD, another terminal of the switch PU12 is coupled to the node ND11. A terminal of the switch PD12 is configured to receive the reference voltage signal VSS, another terminal of the switch PU12 is coupled to the node ND11.

In some embodiments, the reference voltage signal VDD has a power voltage level, and the reference voltage signal VSS has a ground voltage level which is lower than the power voltage level. In some embodiments, the switches PG11, PG12, PD11 and PD12 are implemented by N-type transistors, and the switches PU11 and PU12 are implemented by P-type transistors. In some embodiments, the bit line signals BL1 and BLB1 are complementary with each other. Alternatively stated, when one of the bit line signals BL1 and BLB1 has a logic value of 0, the other one of the bit line signals BL1 and BLB1 has a logic value of 1. In some embodiments, the memory cell 101 corresponds to a static random-access memory, and configured to store data bits in the nodes ND11 and ND12. The nodes ND11 and ND12 are referred to as storage nodes.

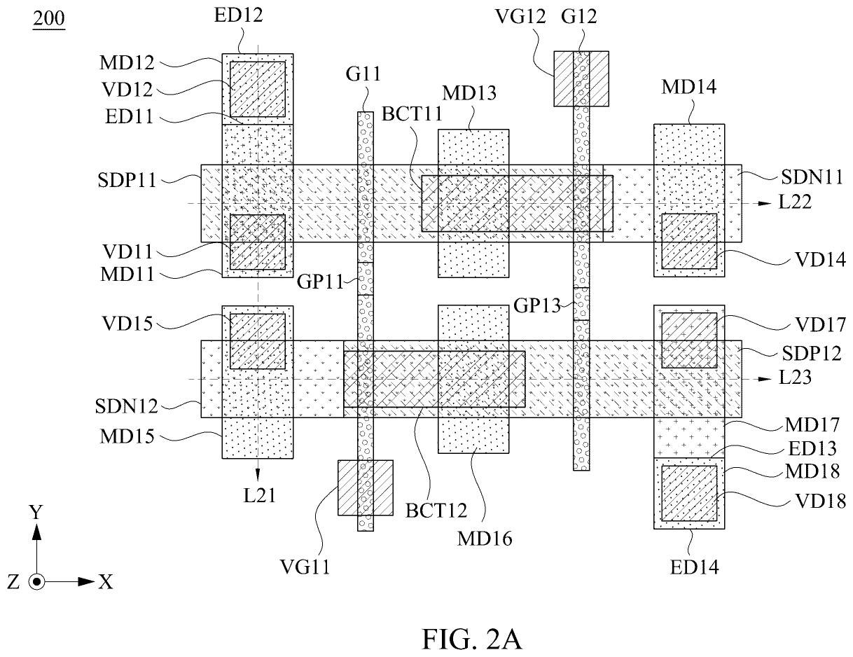

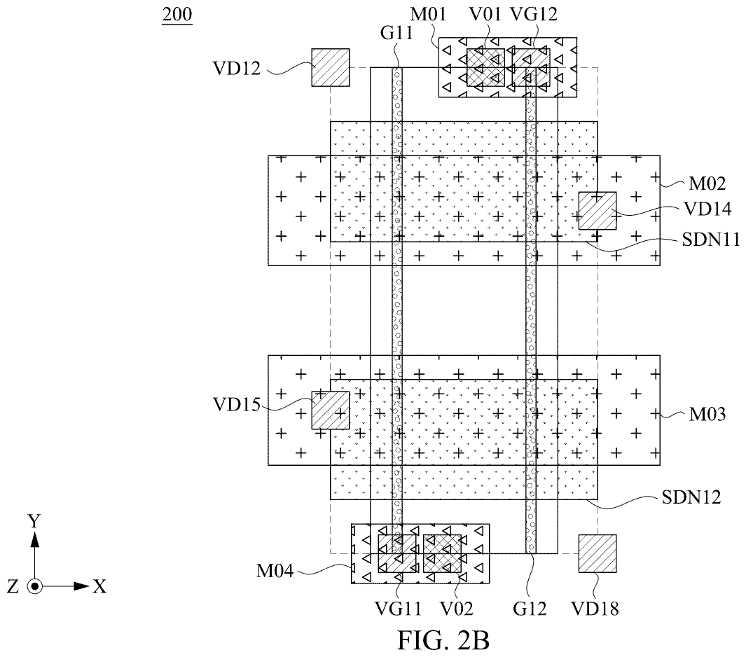

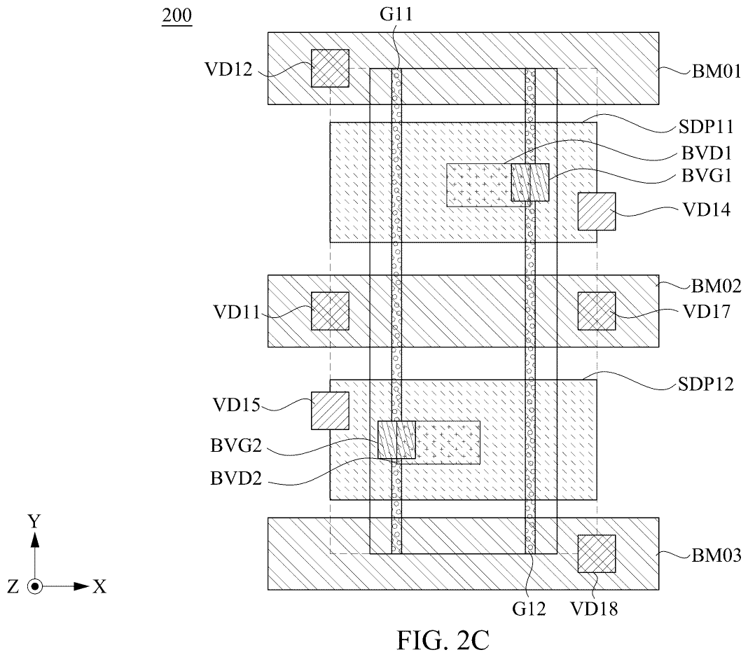

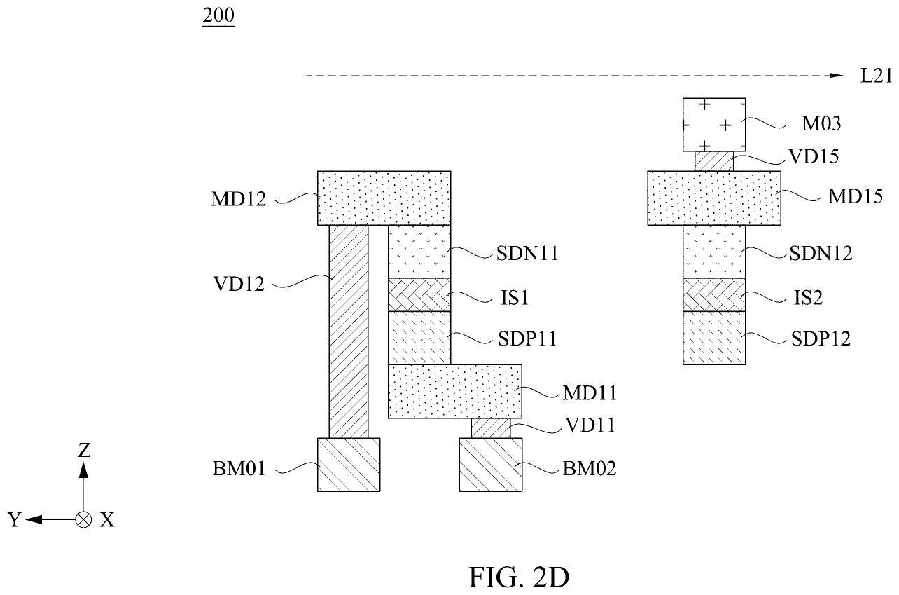

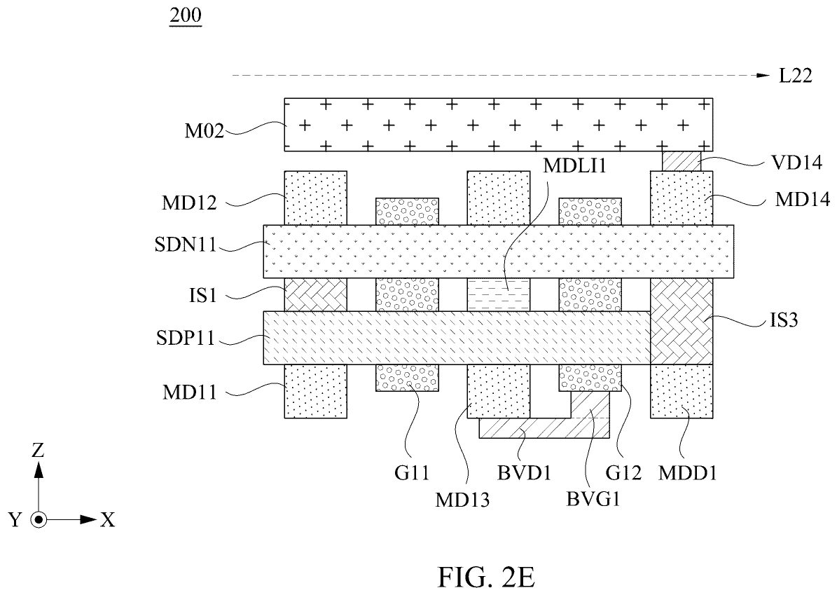

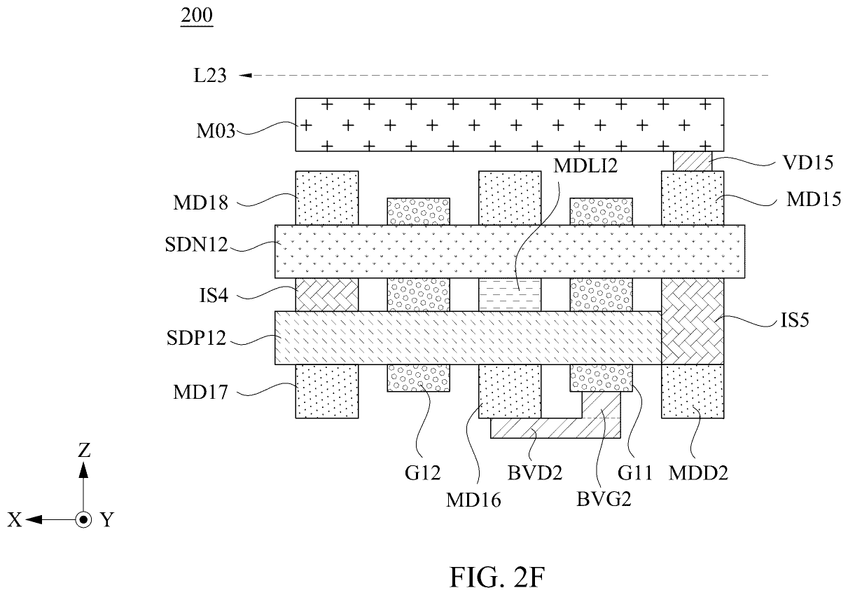

FIG. 2A is a layout diagram of a semiconductor device 200 corresponding to the semiconductor device 100 shown in FIG. 1, illustrated in accordance with some embodiments of the present disclosure. In FIG. 2A, a Z direction points out from the paper.

As illustratively shown in FIG. 2A, the semiconductor device 200 includes source/drain structures SDN11, SDN12, SDP11, SDP12, gate structures G11, G12, conductive segments MD11-MD18, BCT11, BCT12 and the via structures VD11, VD12, VD14, VD15, VD17, VD18, VG11, VG12. Each of the source/drain structures SDN11, SDN12, SDP11, SDP12 and the conductive segments BCT11, BCT12 is elongated along an X direction. Each of the gate structures G11, G12 and the conductive segments MD11-MD18 is elongated along a Y direction. In some embodiments, the X direction, the Y direction and the Z direction are perpendicular with each other.

Along the X direction, the conductive segment MD11, the gate structure G11, the conductive segment MD13, the gate structure G12 and the conductive segment MD14 are arranged in order and are separated from each other. Along the Y direction, the source/drain structures SDN11 and SDN12 are separated from each other.

Each of the conductive segments MD12 and MD15 is aligned with the conductive segment MD11 along the Y direction. The conductive segments MD13 and MD16 are aligned with each other along the Y direction. Each of the conductive segments MD17 and MD18 is aligned with the conductive segment MD14 along the Y direction.

Along the Z direction, the source/drain structures SDN11 and SDN12 are disposed above the source/drain structures SDP11 and SDP12, respectively. In some embodiments, each of the source/drain structures SDN11 and SDN12 is implemented by N-type material, and each of the source/drain structures SDP11 and SDP12 is implemented by P-type material. In some embodiments, the semiconductor device 200 is referred to as a complementary field-effect transistor (CFET) structure.

Each of the conductive segments MD12, MD14 is disposed above, overlapped with and coupled to the source/drain structure SDN11. The conductive segment MD11 is disposed below, overlapped with and coupled to the source/drain structure SDP11. The conductive segment MD13 is disposed between and coupled to the source/drain structures SDN11 and SDP11. Each of the conductive segments MD15, MD18 is disposed above, overlapped with and coupled to the source/drain structure SDN12. The conductive segment MD17 is disposed below, overlapped with and coupled to the source/drain structure SDP12. The conductive segment MD16 is disposed between and coupled to the source/drain structures SDN12 and SDP12.

As illustratively shown in FIG. 2A, the gate structure G11 is coupled to and overlapped with each of the source/drain structure SDN11, SDN12, SDP11, SDP12, and the conductive segment BCT11. The gate structure G12 is coupled to and overlapped with each of the source/drain structure SDN11, SDN12, SDP11, SDP12, and the conductive segment BCT12.

In some embodiments, along the Z direction, the conductive segment BCT11 is disposed below the source/drain structure SDP11, and the conductive segment BCT12 is disposed below the source/drain structure SDP12. The conductive segment BCT11 is configured to couple the conductive segment MD13 to the gate structure G12. The conductive segment BCT12 is configured to couple the conductive segment MD16 to the gate structure G11.

Along the Z direction, the via structure VD11 is disposed below and coupled to the conductive segment MD11, the via structure VD12 is disposed below and coupled to the conductive segment MD12, the via structure VD17 is disposed below and coupled to the conductive segment MD17, the via structure VD18 is disposed below and coupled to the conductive segment MD18, the via structure VD15 is disposed above and coupled to the conductive segment MD15, the via structure VD14 is disposed above and coupled to the conductive segment MD14, the via structure VG11 is disposed above and coupled to the gate structure G11, and the via structure VG12 is disposed above and coupled to the gate structure G12.

As illustratively shown in FIG. 2A, the conductive segments MD11, MD12, MD17 and MD18 includes edges ED11-ED14, respectively. Each of the edges ED11-ED14 elongated along the X direction. Along the Y direction, the via structure VD12 is disposed between and separated from the edges ED11 and ED12, and the via structure VD18 is disposed between and separated from the edges ED13 and ED14. It is noted that the via structures VD12 and VD18 are separated from the source/drain structures SDN11 and SDN12, respectively, along the Y direction.

In some embodiments, the via structures VD12 and VD18 are referred to as deep via structures. Along the Z direction, each of the via structures VD12 and VD18 has a height larger than a distance between the conductive segments MD11 and MD12, and also larger than a distance between the conductive segments MD17 and MD18. Accordingly, the via structures VD11, VD17, VD12 and VD18 are coupled to the same side, such as a back side, of the semiconductor device 200.

Referring to FIG. 1 and FIG. 2A, the semiconductor device 100 is implemented by the semiconductor device 200 in some embodiments. In such embodiments, the switch PG12 is implemented by the source/drain structure SDN11 and the gate structure G12. The switch PG11 is implemented by the source/drain structure SDN12 and the gate structure G11. The switch PD12 is implemented by the source/drain structure SDN11 and the gate structure G11. The switch PD11 is implemented by the source/drain structure SDN12 and the gate structure G12. The switch PU12 is implemented by the source/drain structure SDP11 and the gate structure G11. The switch PU11 is implemented by the source/drain structure SDP12 and the gate structure G12. Specifically, the control terminals of the switches PG11, PD12 and PU12 are implemented by the gate structure G11, and the control terminals of the switches PG12, PD11 and PU11 are implemented by the gate structure G11.

Furthermore, the nodes ND11 and ND12 correspond to the conductive segments BCT11 and BCT12, respectively. The via structure VD11 is configured to transmit the reference voltage signal VDD through the conductive segment MD11 to the source/drain structure SDP11. The via structure VD12 is configured to transmit the reference voltage signal VSS through the conductive segment MD12 to the source/drain structure SDN11. The via structure VD15 is configured to transmit the bit line signal BLB1 through the conductive segment MD15 to the source/drain structure SDN12. The via structure VG11 is configured to transmit the word line signal WL1 to the gate structure G11.

Similarly, the via structure VD17 is configured to transmit the reference voltage signal VDD through the conductive segment MD17 to the source/drain structure SDP12. The via structure VD18 is configured to transmit the reference voltage signal VSS through the conductive segment MD18 to the source/drain structure SDN12. The via structure VD14 is configured to transmit the bit line signal BL1 through the conductive segment MD14 to the source/drain structure SDN11. The via structure VG12 is configured to transmit the word line signal WL1 to the gate structure G12.

In some embodiments, the semiconductor device 200 further includes the back side and a front side opposite to each other. Along the Z direction, the back side is below the source/drain structures SDP11 and SDP12, and the front side is above the source/drain structures SDN11 and SDN12. In some embodiments, the semiconductor device 200 further includes power tracks at the back side and signal tracks at the front side. The power tracks are configured to transmit the reference voltage signals VDD and VSS. The signal tracks are configured to transmit the word line signal WL1 and the bit line signals BL1, BLB1. Accordingly, the via structures VD11, VD12, VD17 and VD18 are configured to receive the reference voltage signals VDD and VSS from the back side.

In some approaches of CFET structures, mixture of power and signal of NMOS and PMOS on both of a front side and a back side of the CFET structures will increase the complexity of circuit design. Accordingly, the front side routing resource of bit lines and word lines are insufficient.

Compared to above approaches, in the embodiments of present disclosure, the power tracks are disposed at the back side of the semiconductor device 200. The via structures VD12 and VD18 are used to transmit the reference voltage signal VSS from the back side to release the front side routing resource of bit lines and word lines. Accordingly, the routing of the semiconductor device 200 is simplified.

FIG. 2B is a layout diagram of further details of the semiconductor device 200 shown in FIG. 2A, illustrated in accordance with some embodiments of the present disclosure. In FIG. 2B, the Z direction points out from the paper.

As illustratively shown in FIG. 2B, the semiconductor device 200 further includes conductive segments M01-M04, M11 and via structures V01, V02. The conductive segments M01-M04 are disposed above the gate structures G11-G12 and the source/drain structures SDN11, SDN12 along the Z direction, and are arranged in order and separated from each other along the Y direction. The conductive segment M11 is disposed above and overlapped with each of the conductive segments M01-M04, and arranged between the via structures VD12 and VD18 along the X direction. The conductive segment M01 is coupled to each of the via structures VG12 and V01. The conductive segment M04 is coupled to each of the via structures VG11 and V02. The conductive segment M11 is coupled to each of the via structures V01 and V02.

Referring to FIG. 1 and FIG. 2B, in some embodiments, the conductive segment M11 is configured to transmit the word line signal WL1 through the via structures V01, VG12 and the conductive segment M01 to the gate structure G12, and transmit the word line signal WL1 through the via structures V02, VG11 and the conductive segment M04 to the gate structure G11. The conductive segment M02 is configured to transmit the bit line signal BL1 to the via structure VD14. The conductive segment M03 is configured to transmit the bit line signal BLB1 to the via structure VD15.

FIG. 2C is a layout diagram of further details of the semiconductor device 200 shown in FIG. 2A, illustrated in accordance with some embodiments of the present disclosure. In FIG. 2C, the Z direction points out from the paper.

As illustratively shown in FIG. 2C, the semiconductor device 200 further includes conductive segments BM01-BM03, BVD1, BVD2 and BVG1, BVG2. The conductive segments BM01-BM03, BVD1, BVD2 and BVG1, BVG2 are disposed below the gate structures G11-G12 and the source/drain structures SDP11, SDP12 along the Z direction. Along the Y direction, the conductive segment BM01, the source/drain structure SDP11, the conductive segment BM02, the source/drain structure SDP12 and the conductive segment BM03 are arranged in order and are separated from each other. The conductive segment BVG1 is coupled between the gate structure G12 and the conductive segment BVD1. The conductive segment BVG2 is coupled between the gate structure G11 and the conductive segment BVD2.

Referring to FIG. 2A and FIG. 2C, the conductive segments BVD1 and BVG1 are included in the conductive segment BCT11, and the conductive segments BVD2 and BVG2 are included in the conductive segment BCT12. Accordingly, each of the conductive segments BVD1 and BVG1 is overlapped with the source/drain structure SDP11, and each of the conductive segments BVD2 and BVG2 is overlapped with the source/drain structure SDP12.

Referring to FIG. 1 and FIG. 2C, in some embodiments, the conductive segment BM01 is configured to transmit the reference voltage signal VSS to the via structure VD12. The conductive segment BM03 is configured to transmit the reference voltage signal VSS to the via structure VD18. The conductive segment BM02 is configured to transmit the reference voltage signal VDD to each of the via structures VD11 and VD17.

FIG. 2D is a cross sectional diagram along a line L21 of the semiconductor device 200 shown in FIG. 2A, illustrated in accordance with some embodiments of the present disclosure. In FIG. 2D, the X direction points into the paper.

As illustratively shown in FIG. 2D, the semiconductor device 200 further includes isolation structures IS1 and IS2. The isolation structure IS1 is disposed between and configured to isolate the source/drain structures SDN11 and SDP11 from each other. The isolation structure IS2 is disposed between and configured to isolate the source/drain structures SDN12 and SDP12 from each other.

Along the Z direction, the height of the via structure VD12 is approximately equal to a distance between the conductive segments MD12 and BM01. In some embodiments, the height of the via structure VD12 is approximately equal to a summation of heights of the source/drain structures SDN11, SDP11, the isolation structure IS1, the conductive segment MD11 and the via structure VD11 along the Z direction. Referring to FIG. 2D and FIG. 2A, the via structure VD18 is similar with the via structure VD12. Along the Z direction, the height of the via structure VD18 is approximately equal to a distance between the conductive segments MD18 and BM03.

FIG. 2E is a cross sectional diagram along a line L22 of the semiconductor device 200 shown in FIG. 2A, illustrated in accordance with some embodiments of the present disclosure. In FIG. 2E, the Y direction points out from the paper.

As illustratively shown in FIG. 2E, the semiconductor device 200 further includes isolation structures IS3 and conductive segments MDD1 and MDLI1. The isolation structure IS3 is disposed between the conductive segment MDD1 and the source/drain structure SDN11 along the Z direction, and is configured to isolate the conductive segment MDD1 and the source/drain structures SDN11, SDP11 from each other. The conductive segment MDLI1 is disposed between and coupled to the source/drain structures SDN11 and SDP11. The conductive segments BVD1 and BVG1 are configured to couple the gate structure G12 and the conductive segment MD13 to each other.

FIG. 2F is a cross sectional diagram along a line L23 of the semiconductor device 200 shown in FIG. 2A, illustrated in accordance with some embodiments of the present disclosure. In FIG. 2F, the Y direction points into the paper.

As illustratively shown in FIG. 2F, the semiconductor device 200 further includes isolation structures IS4, IS5 and conductive segments MDD2, MDLI2. The isolation structure IS4 is disposed between the source/drain structures SDN12 and SDP12 to isolate the source/drain structures SDN12 and SDP12 from each other along the Z direction. The isolation structure IS5 is disposed between the conductive segment MDD2 and the source/drain structure SDN12 along the Z direction, and is configured to isolate the conductive segment MDD2 and the source/drain structures SDN12, SDP12 from each other. The conductive segment MDLI2 is disposed between and coupled to the source/drain structures SDN12 and SDP12. The conductive segments BVD2 and BVG2 are configured to couple the gate structure G11 and the conductive segment MD16 to each other.

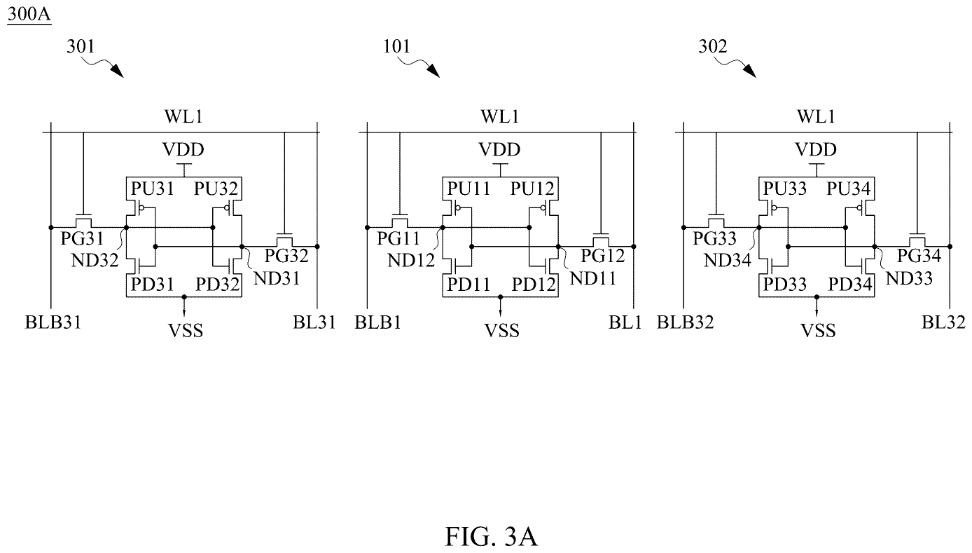

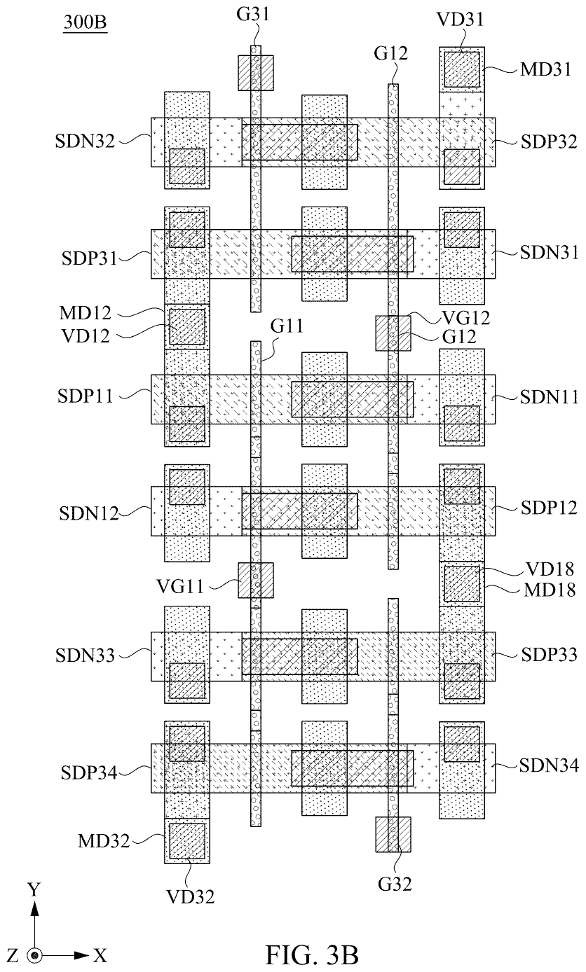

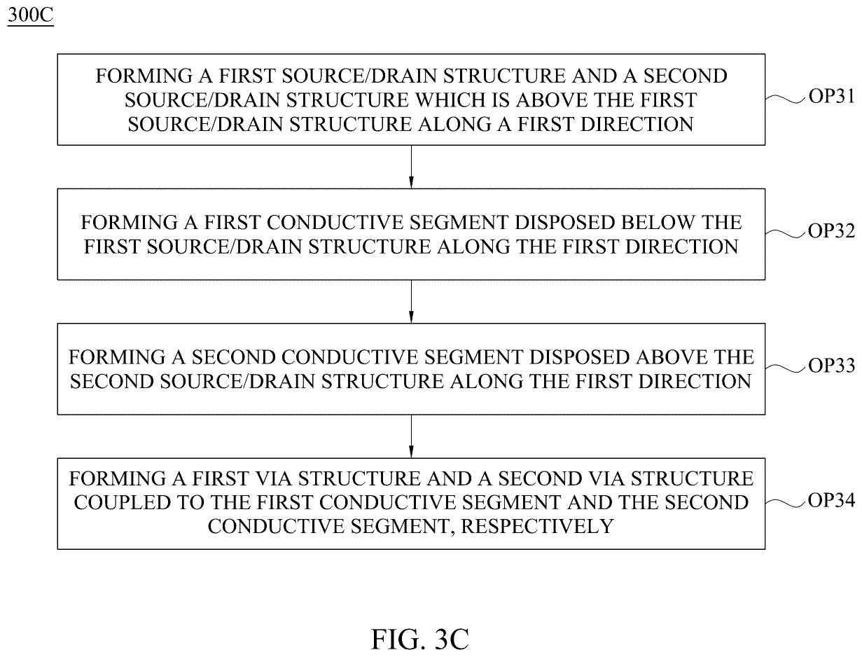

FIG. 3A is a circuit diagram of a semiconductor device 300A corresponding to the semiconductor device 100 shown in FIG. 1, illustrated in accordance with some embodiments of the present disclosure. Referring to FIG. 1 and FIG. 3A, the semiconductor device 300A is an alternative embodiment of the semiconductor device 100. FIG. 3A follows a similar labeling convention to that of FIG. 1. For brevity, the discussion will focus more on differences between the semiconductor device 300A and the semiconductor device 100 than on similarities. Compared to the semiconductor device 100, the semiconductor device 300A further includes memory cells 301 and 302.

As illustratively shown in FIG. 3A, the memory cell 301 includes switches PG31, PG32, PU31, PU32, PD31 and PD32. Each of control terminals of the switches PG31 and PG32 is configured to receive the word line signal WL1. A terminal of the switch PG31 is configured to receive a bit line signal BLB31, and another terminal of the switch PG31 is coupled to a node ND32. A terminal of the switch PG32 is configured to receive a bit line signal BL31, and another terminal of the switch PG32 is coupled to a node ND31. Each of control terminals of the switches PU31 and PD31 is coupled to the node ND31. A terminal of the switch PU31 is configured to receive the reference voltage signal VDD, another terminal of the switch PU31 is coupled to the node ND32. A terminal of the switch PD31 is configured to receive the reference voltage signal VSS, another terminal of the switch PU31 is coupled to the node ND32. Each of control terminals of the switches PU32 and PD32 is coupled to the node ND32. A terminal of the switch PU32 is configured to receive the reference voltage signal VDD, another terminal of the switch PU32 is coupled to the node ND31. A terminal of the switch PD32 is configured to receive the reference voltage signal VSS, another terminal of the switch PU32 is coupled to the node ND31.

Similarly, the memory cell 302 includes switches PG33, PG34, PU33, PU34, PD33 and PD34. Each of control terminals of the switches PG33 and PG34 is configured to receive the word line signal WL1. A terminal of the switch PG33 is configured to receive a bit line signal BLB32, and another terminal of the switch PG33 is coupled to a node ND34. A terminal of the switch PG34 is configured to receive a bit line signal BL32, and another terminal of the switch PG34 is coupled to a node ND33. Each of control terminals of the switches PU33 and PD33 is coupled to the node ND33. A terminal of the switch PU33 is configured to receive the reference voltage signal VDD, another terminal of the switch PU33 is coupled to the node ND34. A terminal of the switch PD33 is configured to receive the reference voltage signal VSS, another terminal of the switch PU33 is coupled to the node ND34. Each of control terminals of the switches PU34 and PD34 is coupled to the node ND34. A terminal of the switch PU34 is configured to receive the reference voltage signal VDD, another terminal of the switch PU34 is coupled to the node ND33. A terminal of the switch PD34 is configured to receive the reference voltage signal VSS, another terminal of the switch PU34 is coupled to the node ND33.

In some embodiments, the switches PG31-PG34 and PD31-PD34 are implemented by N-type transistors, and the switches PU31-PU34 are implemented by P-type transistors. In some embodiments, the bit line signals BL31 and BLB31 are complementary with each other, and the bit line signals BL32 and BLB32 are complementary with each other. The nodes ND31-ND34 are referred to as storage nodes.

FIG. 3B is a circuit diagram of a semiconductor device 300B corresponding to the semiconductor device 200 shown in FIG. 2A, illustrated in accordance with some embodiments of the present disclosure. Referring to FIG. 2A and FIG. 3B, the semiconductor device 300B is an alternative embodiment of the semiconductor device 200. FIG. 3B follows a similar labeling convention to that of FIG. 2A. For brevity, the discussion will focus more on differences between the semiconductor device 300B and the semiconductor device 200 than on similarities, and some labels shown in FIG. 2A are not shown in FIG. 3B.

Compared to the semiconductor device 200, the semiconductor device 300B further includes source/drain structures SDP31-SDP34, SDN31-SDN34, gate structures G31, G32, conductive segments MD31, MD32 and via structures VD31, VD32.

As illustratively shown in FIG. 3A, along the Z direction, the source/drain structures SDN31-SDN34 are disposed directly above the source/drain structures SDP31-SDP34, respectively. The source/drain structures SDN34, SDN33, SDN12, SDN11, SDN31 and SDN32 are arranged in order, and are separated from each other along the Y direction.

The gate structure G11 is further overlapped with and coupled to each of the source/drain structures SDN33, SDN34, SDP33 and SDP34. The gate structure G12 is further overlapped with and coupled to each of the source/drain structures SDN31, SDN32, SDP31 and SDP32. Along the Y direction, the gate structures G31 and G32 are aligned with and separated from the gate structure G11 and G12, respectively. The gate structure G31 is further overlapped with and coupled to each of the source/drain structures SDN31, SDN32, SDP31 and SDP32. The gate structure G32 is further overlapped with and coupled to each of the source/drain structures SDN33, SDN34, SDP33 and SDP34.

The conductive segment MD12 is further overlapped with the source/drain structure SDN31 and couples the via structure VD12 to the source/drain structure SDN31. The conductive segment MD18 is further overlapped with the source/drain structure SDN33 and couples the via structure VD18 to the source/drain structure SDN33.

Along the Z direction, the conductive segment MD31 is disposed above and coupled to each of the via structure VD31 and the source/drain structure SDN32, and the conductive segment MD32 is disposed above and coupled to each of the via structure VD32 and the source/drain structure SDN34. Referring to FIG. 2D and FIG. 3B, the via structures VD31 and VD32 are similar with the via structure VD12, and are referred to as deep via structures. Accordingly, along the Z direction, each of heights of the via structures VD31 and VD32 is approximately equal to the height of the via structure VD12.

Referring to FIG. 3A and FIG. 3B, the semiconductor device 300A is implemented by the semiconductor device 300B in some embodiments. Accordingly, the switch PG31 is implemented by the gate structure G31 and the source/drain structure SDN32. The switch PG32 is implemented by the gate structure G12 and the source/drain structure SDN31. The switch PD31 is implemented by the gate structure G12 and the source/drain structure SDN32. The switch PU31 is implemented by the gate structure G12 and the source/drain structure SDP32. The switch PD32 is implemented by the gate structure G31 and the source/drain structure SDN31. The switch PU32 is implemented by the gate structure G31 and the source/drain structure SDP31.

Similarly, the switch PG33 is implemented by the gate structure G11 and the source/drain structure SDN33. The switch PG34 is implemented by the gate structure G32 and the source/drain structure SDN34. The switch PD33 is implemented by the gate structure G32 and the source/drain structure SDN33. The switch PU33 is implemented by the gate structure G32 and the source/drain structure SDP33. The switch PD34 is implemented by the gate structure G11 and the source/drain structure SDN34. The switch PU34 is implemented by the gate structure G11 and the source/drain structure SDP34.

In such embodiments, the via structure VD31 is configured to transmit the reference voltage signal VSS through the conductive segment MD31 to the switch PD31. The via structure VD32 is configured to transmit the reference voltage signal VSS through the conductive segment MD32 to the switch PD34. The via structure VD12 is configured to transmit the reference voltage signal VSS through the conductive segment MD12 to each of the switches PD12 and PD32. The via structure VD18 is configured to transmit the reference voltage signal VSS through the conductive segment MD18 to each of the switches PD11 and PD33. Alternatively stated, the via structure VD12 is shared by the memory cells 101 and 301, and the via structure VD18 is shared by the memory cells 101 and 302, for transmitting the reference voltage signal VSS.

FIG. 3C is a flowchart diagram of a method 300C for fabricating the semiconductor devices described above, illustrated in accordance with some embodiments of the present disclosure. The method 300C includes operations OP31-OP34.

During the operation OP31, a first source/drain structure and a second source/drain structure which is above the first source/drain structure along a first direction are formed. For example, the source/drain structure SDP11 and the source/drain structure SDN11 which is above the source/drain structure SDP11 along the Z direction are formed.

During the operation OP32, a first conductive segment disposed below the first source/drain structure along the first direction is formed. For example, the conductive segment MD11 disposed below the source/drain structure SDP11 along the Z direction is formed.

During the operation OP33, a second conductive segment disposed above the second source/drain structure along the first direction is formed. For example, the conductive segment MD12 disposed above the source/drain structure SDN11 along the Z direction is formed.

During the operation OP34, a first via structure and a second via structure respectively coupled to the first conductive segment and the second conductive segment are formed. For example, the via structures VD11 and VD12 respectively coupled to the conductive segments MD11 and MD12 are formed.

In some embodiments, the first via structure is configured to transmit a first reference voltage signal from a first side through the first conductive segment to the first source/drain structure, the second via structure is configured to transmit a second reference voltage signal from the first side through the second conductive segment to the second source/drain structure, and the first reference voltage signal and the second reference voltage signal are different from each other.

For example, the via structure VD11 is configured to transmit the reference voltage signal VDD from the back side through the conductive segment MD11 to the source/drain structure SDP11, the via structure VD12 is configured to transmit the reference voltage signal VSS from the back side through the conductive segment MD12 to the source/drain structure SDN11, and the reference voltage signal VDD and VSS are different from each other.

In some embodiments, the method further includes forming a third source/drain structure and a fourth source/drain structure which is above the third source/drain structure along the first direction, forming a third conductive segment disposed below the third source/drain structure along the first direction, forming a fourth conductive segment disposed above the fourth source/drain structure along the first direction, and forming a third via structure and a fourth via structure coupled to the first conductive segment and the fourth conductive segment, respectively. The third via structure is configured to transmit the first reference voltage signal from the first side through the third conductive segment to the third source/drain structure, and the fourth via structure is configured to transmit the second reference voltage signal from the first side through the fourth conductive segment to the fourth source/drain structure.

For example, the source/drain structure SDP12 and the source/drain structure SDN12 which is above the source/drain structure SDP12 along the Z direction are formed. The conductive segment MD17 disposed below the source/drain structure SDP12 along the Z direction is formed. The conductive segment MD18 disposed above the source/drain structure SDN12 along the Z direction is formed. The via structures VD17 and VD18 respectively coupled to the conductive segments MD17 and MD18 are formed. The via structure VD17 is configured to transmit the reference voltage signal VDD from the back side through the conductive segment MD17 to the source/drain structure SDP12, and the via structure VD18 is configured to transmit the reference voltage signal VSS from the back side through the conductive segment MD18 to the source/drain structure SDN12.

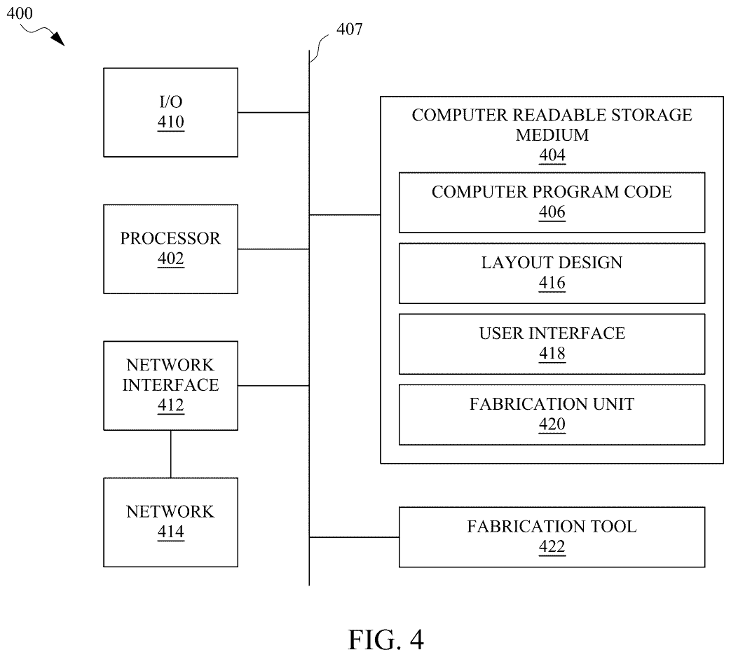

FIG. 4 is a schematic view of a system 400 for designing and manufacturing at least one of the semiconductor devices as described herein, in accordance with some embodiments of the present disclosure. The system 400 generates or places one or more IC layout designs corresponding to at least one of the semiconductor devices as described herein. In some embodiments, the system 400 manufactures one or more semiconductor devices based on the one or more IC layout designs, as described herein. The system 400 includes a hardware processor 402 and a non-transitory, computer readable storage medium 404 encoded with, e.g., storing, the computer program code 406, e.g., a set of executable instructions. The computer readable storage medium 404 is configured for interfacing with manufacturing machines for producing the semiconductor device. The processor 402 is electrically coupled to the computer readable storage medium 404 by a bus 407. The processor 402 is also electrically coupled to an I/O interface 410 by the bus 407. A network interface 412 is also electrically connected to the processor 402 by the bus 407. Network interface 412 is connected to a network 414, so that the processor 402 and the computer readable storage medium 404 are capable of connecting to external elements via network 414. The processor 402 is configured to execute the computer program code 406 encoded in the computer readable storage medium 404 in order to cause the system 400 designing and manufacturing at least one of the semiconductor devices as described herein.

In some embodiments, the processor 402 is a central processing unit (CPU), a multi-processor, a distributed processing system, an application specific integrated circuit (ASIC), and/or a suitable processing unit.

In some embodiments, the computer readable storage medium 404 is an electronic, magnetic, optical, electromagnetic, infrared, and/or a semiconductor system (or apparatus or device). For example, the computer readable storage medium 404 includes a semiconductor or solid-state memory, a magnetic tape, a removable computer diskette, a random access memory (RAM), a read-only memory (ROM), a rigid magnetic disk, and/or an optical disk. In some embodiments using optical disks, the computer readable storage medium 404 includes a compact disk-read only memory (CD-ROM), a compact disk-read/write (CD-R/W), and/or a digital video disc (DVD).

In some embodiments, the storage medium 404 also stores information needed for designing and manufacturing at least one of the semiconductor devices as described herein, such as layout design 416, user interface 418, fabrication unit 420, and/or a set of executable instructions to designing and manufacturing at least one of the semiconductor devices as described herein.

In some embodiments, the storage medium 404 stores instructions (e.g., the computer program code 406) for interfacing with manufacturing machines. The instructions (e.g., the computer program code 406) enable the processor 402 to generate manufacturing instructions readable by the manufacturing machines to effectively implement the semiconductor devices as described herein.

The system 400 includes the I/O interface 410. The I/O interface 410 is coupled to external circuitry. In some embodiments, the I/O interface 410 includes a keyboard, keypad, mouse, trackball, trackpad, and/or cursor direction keys for communicating information and commands to the processor 402.

The system 400 also includes the network interface 412 coupled to the processor 402. The network interface 412 allows the system 400 to communicate with the network 414, to which one or more other computer systems are connected. The network interface 412 includes wireless network interfaces such as BLUETOOTH, WIFI, WIMAX, GPRS, or WCDMA; or wired network interface such as ETHERNET, USB, or IEEE-13144. In some embodiments, the designing and manufacturing of at least one of the semiconductor devices as described herein is implemented in two or more systems 400, and information such as layout design, user interface and fabrication unit are exchanged between different systems 400 by the network 414.

The system 400 is configured to receive information related to a layout design through the I/O interface 410 or network interface 412. The information is transferred to the processor 402 by the bus 407 to determine a layout design for producing an IC. The layout design is then stored in the computer readable medium 404 as the layout design 416. The system 400 is configured to receive information related to a user interface through the I/O interface 410 or network interface 412. The information is stored in the computer readable medium 404 as the user interface 418. The system 400 is configured to receive information related to a fabrication unit through the I/O interface 410 or network interface 412. The information is stored in the computer readable medium 404 as the fabrication unit 420. In some embodiments, the fabrication unit 420 includes fabrication information utilized by the system 400.

In some embodiments, the designing and manufacturing of at least one of the semiconductor devices as described herein is implemented as a standalone software application for execution by a processor. In some embodiments, the designing and manufacturing of at least one of the semiconductor devices as described herein is implemented as a software application that is a part of an additional software application. In some embodiments, the designing and manufacturing of at least one of the semiconductor devices as described herein is implemented as a plug-in to a software application. In some embodiments, the designing and manufacturing of at least one of the semiconductor devices as described herein is implemented as a software application that is a portion of an EDA tool. In some embodiments, the designing and manufacturing of at least one of the semiconductor devices as described herein is implemented as a software application that is used by an EDA tool. In some embodiments, the EDA tool is used to generate a layout design of the integrated circuit device. In some embodiments, the layout design is stored on a non-transitory computer readable medium. In some embodiments, the layout design is generated using a tool such as VIRTUOSO® available from CADENCE DESIGN SYSTEMS, Inc., or another suitable layout generating tool. In some embodiments, the layout design is generated based on a netlist which is created based on the schematic design. In some embodiments, at least one of the semiconductor devices as described herein is implemented by a manufacturing device to manufacture an integrated circuit using a set of masks manufactured based on one or more layout designs generated by the system 400. In some embodiments, the system 400 includes a manufacturing device (e.g., fabrication tool 422) to manufacture an integrated circuit using a set of masks manufactured based on one or more layout designs of the present disclosure.

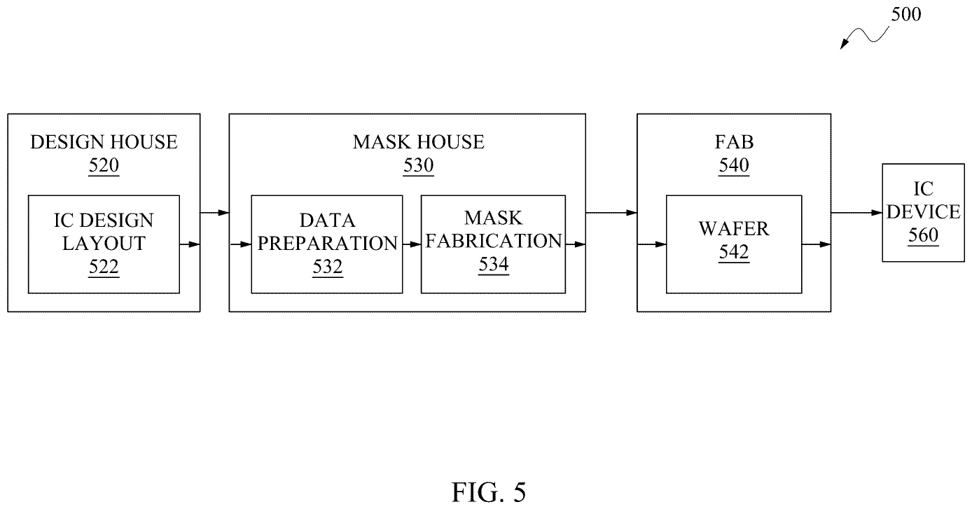

FIG. 5 is a block diagram of an integrated circuit (IC)/semiconductor device manufacturing system 500, and an IC manufacturing flow associated therewith, in accordance with some embodiments of the present disclosure. Referring to FIG. 3C and FIG. 5, the method 300C is performed by the IC manufacturing system 500 in some embodiments.

In FIG. 5, the IC manufacturing system 500 includes entities, such as a design house 520, a mask house 530, and an IC manufacturer/fabricator (“fab”) 540, that interact with one another in the design, development, and manufacturing cycles and/or services related to manufacturing an IC device (semiconductor device) 560 including at least one of the semiconductor devices as described herein. The entities in system 500 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 520, mask house 530, and IC fab 540 is owned by a single company. In some embodiments, two or more of design house 520, mask house 530, and IC fab 540 coexist in a common facility and use common resources.

The design house (or design team) 520 generates an IC design layout 522. The IC design layout 522 includes various geometrical patterns designed for the IC device 560. The geometrical patterns correspond to patterns of metal, oxide, or semiconductor layers that make up the various components of the IC device 560 to be fabricated. The various layers combine to form various IC features. For example, a portion of the IC design layout 522 includes various IC features, such as an active region, gate structures, source/drain structures, interconnect structures, and openings for bonding pads, to be formed in a semiconductor substrate (such as a silicon wafer) and various material layers disposed on the semiconductor substrate. The design house 520 implements a proper design procedure to form the IC design layout 522. The design procedure includes one or more of logic design, physical design or place and route. The IC design layout 522 is presented in one or more data files having information of the geometrical patterns. For example, the IC design layout 522 can be expressed in a GDSII file format or DFII file format.

The mask house 530 includes mask data preparation 532 and mask fabrication 534. The mask house 530 uses the IC design layout 522 to manufacture one or more masks to be used for fabricating the various layers of the IC device 560 according to the IC design layout 522. The mask house 530 performs the mask data preparation 532, where the IC design layout 522 is translated into a representative data file (“RDF”). The mask data preparation 532 provides the RDF to the mask fabrication 534. The mask fabrication 534 includes a mask writer. A mask writer converts the RDF to an image on a substrate, such as a mask (reticle) or a semiconductor wafer, or a metal layer which is formed and thereafter selectively etched to form a redistribution layer at a back end of line process of the fab. The design layout is manipulated by the mask data preparation 532 to comply with particular characteristics of the mask writer and/or requirements of the IC fab 540. In FIG. 5, the mask data preparation 532 and mask fabrication 534 are illustrated as separate elements. In some embodiments, the mask data preparation 532 and mask fabrication 534 can be collectively referred to as mask data preparation.

In some embodiments, the mask data preparation 532 includes optical proximity correction (OPC) which uses lithography enhancement techniques to compensate for image errors, such as those that can arise from diffraction, interference, other process effects and the like. OPC adjusts the IC design layout 522. In some embodiments, the mask data preparation 532 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, the mask data preparation 532 includes a mask rule checker (MRC) that checks the IC design layout that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout to compensate for limitations during the mask fabrication 534, which may undo part of the modifications performed by OPC in order to meet mask creation rules.

In some embodiments, the mask data preparation 532 includes lithography process checking (LPC) that simulates processing that will be implemented by the IC fab 540 to fabricate the IC device 560. LPC simulates this processing based on the IC design layout 522 to create a simulated manufactured device, such as the IC device 560. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC can be repeated to further refine the IC design layout 522.

It should be understood that the above description of the mask data preparation 532 has been simplified for the purposes of clarity. In some embodiments, the mask data preparation 532 includes additional features such as a logic operation (LOP) to modify the IC design layout according to manufacturing rules. Additionally, the processes applied to the IC design layout 522 during the mask data preparation 532 may be executed in a variety of different orders.

After the mask data preparation 532 and during mask fabrication 534, a mask or a group of masks are fabricated based on the modified IC design layout. In some embodiments, an electron-beam (e-beam) or a mechanism of multiple e-beams is used to form a pattern on a mask (photomask or reticle) based on the modified IC design layout. The mask can be formed in various technologies. In some embodiments, the mask is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask includes a transparent substrate (e.g., fused quartz) and an opaque material (e.g., chromium) coated in the opaque regions of the mask. In another example, the mask is formed using a phase shift technology. In the phase shift mask (PSM), various features in the pattern formed on the mask are configured to have proper phase difference to enhance the resolution and imaging quality. In various examples, the phase shift mask can be attenuated PSM or alternating PSM. The mask(s) generated by the mask fabrication 534 is used in a variety of processes. For example, such a mask(s) is used in an ion implantation process to form various doped regions in the semiconductor wafer, in an etching process to form various etching regions in the semiconductor wafer, and/or in other suitable processes.

The IC fab 540 is an IC fabrication entity that includes one or more manufacturing facilities for the fabrication of a variety of different IC products. In some embodiments, the IC fab 540 is a semiconductor foundry. For example, there may be a first manufacturing facility for the front end fabrication of a plurality of IC products (e.g., source/drain structures, gate structures), while a second manufacturing facility may provide the middle end fabrication for the interconnection of the IC products (e.g., MDs, VDs, VGs) and a third manufacturing facility may provide the back end fabrication for the interconnection and packaging of the IC products (e.g., M0 tracks, M1 tracks, BM0 tracks, BM1 tracks), and a fourth manufacturing facility may provide other services for the foundry entity.

The IC fab 540 uses the mask (or masks) fabricated by the mask house 530 to fabricate the IC device 560. Thus, the IC fab 540 at least indirectly uses the IC design layout 522 to fabricate the IC device 560. In some embodiments, a semiconductor wafer is fabricated by the IC fab 540 using the mask (or masks) to form the IC device 560. The semiconductor wafer 542 includes a silicon substrate or other proper substrate having material layers formed thereon. Semiconductor wafer further includes one or more of various doped regions, dielectric features, multilevel interconnects, and the like (formed at subsequent manufacturing steps).

Also disclosed is a device. The device a first source/drain structure, a second source/drain structure, a first conductive segment, a second conductive segment, a first via structure and a second via structure. The second source/drain structure is disposed above the first source/drain structure along a first direction. The first conductive segment is disposed below the first source/drain structure along the first direction. The second conductive segment is disposed above the second source/drain structure along the first direction. The first via structure is coupled to the first conductive segment, and configured to transmit a first reference voltage signal from a first side through the first conductive segment to the first source/drain structure. The second via structure is coupled to the second conductive segment, and configured to transmit a second reference voltage signal from the first side through the second conductive segment to the second source/drain structure. The first reference voltage signal and the second reference voltage signal are different from each other.

Also disclosed is a device. The device a first source/drain structure, a second source/drain structure, a first conductive segment, a second conductive segment, a first via structure and a second via structure. The second source/drain structure is disposed above the first source/drain structure along a first direction. The first conductive segment is disposed below the first source/drain structure along the first direction. The second conductive segment is disposed above the second source/drain structure along the first direction. The first via structure is coupled to the first conductive segment, and configured to transmit a first reference voltage signal through the first conductive segment to the first source/drain structure. The second via structure coupled to the second conductive segment, configured to transmit a second reference voltage signal through the second conductive segment to the second source/drain structure, and has a height larger than a distance between the first conductive segment and the second conductive segment along the first direction. The first reference voltage signal and the second reference voltage signal are different from each other.

Also disclosed is a method. The method includes: forming a first source/drain structure and a second source/drain structure which is above the first source/drain structure along a first direction; forming a first conductive segment disposed below the first source/drain structure along the first direction; forming a second conductive segment disposed above the second source/drain structure along the first direction; and forming a first via structure and a second via structure coupled to the first conductive segment and the second conductive segment, respectively. The first via structure is configured to transmit a first reference voltage signal from a first side through the first conductive segment to the first source/drain structure, the second via structure is configured to transmit a second reference voltage signal from the first side through the second conductive segment to the second source/drain structure, and the first reference voltage signal and the second reference voltage signal are different from each other.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a first source/drain structure;
a second source/drain structure disposed above the first source/drain structure along a first direction;
a first conductive segment disposed below the first source/drain structure along the first direction;
a second conductive segment disposed above the second source/drain structure along the first direction;
a first via structure coupled to the first conductive segment, and configured to transmit a first reference voltage signal from a first side through the first conductive segment to the first source/drain structure; and
a second via structure coupled to the second conductive segment, and configured to transmit a second reference voltage signal from the first side through the second conductive segment to the second source/drain structure,
wherein the first reference voltage signal and the second reference voltage signal are different from each other.

2. The device of claim 1, wherein the first conductive segment and the second conductive segment comprise a first edge and a second edge, respectively, and
the second via structure is disposed between the first edge and the second edge.

3. The device of claim 2, wherein the second via structure is separated from the second source/drain structure along a second direction different from the first direction, and
the second via structure is disposed between the first edge and the second edge along the second direction.

4. The device of claim 1, wherein along the first direction, the second via structure has a height larger than a distance between the first conductive segment and the second conductive segment.

5. The device of claim 1, further comprising:
a third source/drain structure;
a fourth source/drain structure disposed above the third source/drain structure along the first direction;
a third conductive segment disposed below the third source/drain structure along the first direction;
a fourth conductive segment disposed above the fourth source/drain structure along the first direction;
a third via structure coupled to the third conductive segment, and configured to transmit the first reference voltage signal from the first side through the third conductive segment to the third source/drain structure; and
a fourth via structure coupled to the fourth conductive segment, and configured to transmit the second reference voltage signal from the first side through the fourth conductive segment to the fourth source/drain structure.

6. The device of claim 5, wherein the third conductive segment and the fourth conductive segment comprise a first edge and a second edge, respectively, and
the fourth via structure is disposed between the first edge and the second edge.

7. The device of claim 6, wherein the fourth via structure is separated from the fourth source/drain structure along a second direction different from the first direction, and
the fourth via structure is disposed between the first edge and the second edge along the second direction.

8. The device of claim 5, wherein along the first direction, the fourth via structure has a height larger than a distance between the third conductive segment and the fourth conductive segment.

9. A device, comprising:
a first source/drain structure;
a second source/drain structure disposed above the first source/drain structure along a first direction;
a first conductive segment disposed below the first source/drain structure along the first direction;
a second conductive segment disposed above the second source/drain structure along the first direction;
a first via structure coupled to the first conductive segment, and configured to transmit a first reference voltage signal through the first conductive segment to the first source/drain structure; and
a second via structure coupled to the second conductive segment, configured to transmit a second reference voltage signal through the second conductive segment to the second source/drain structure, and having a height larger than a distance between the first conductive segment and the second conductive segment along the first direction,
wherein the first reference voltage signal and the second reference voltage signal are different from each other.

10. The device of claim 9, wherein the first conductive segment and the second conductive segment comprise a first edge and a second edge, respectively, and
the second via structure is disposed between the first edge and the second edge.

11. The device of claim 10, wherein the second via structure is separated from
the second source/drain structure along a second direction different from the first direction, and
the second via structure is disposed between the first edge and the second edge along the second direction.

12. The device of claim 9, further comprising:
a third source/drain structure;
a fourth source/drain structure disposed above the third source/drain structure along the first direction;
a third conductive segment disposed below the third source/drain structure along the first direction;
a fourth conductive segment disposed above the fourth source/drain structure along the first direction;
a third via structure coupled to the third conductive segment, and configured to transmit the first reference voltage signal through the third conductive segment to the third source/drain structure, and having a height larger than a distance between the third conductive segment and the fourth conductive segment along the first direction; and
a fourth via structure coupled to the fourth conductive segment, and configured to transmit the second reference voltage signal through the fourth conductive segment to the fourth source/drain structure.

13. The device of claim 12, wherein the third conductive segment and the fourth conductive segment comprise a first edge and a second edge, respectively, and
the fourth via structure is disposed between the first edge and the second edge.

14. The device of claim 13, wherein the fourth via structure is separated from the fourth source/drain structure along a second direction different from the first direction, and
the fourth via structure is disposed between the first edge and the second edge along the second direction.

15. A method, comprising:
forming a first source/drain structure and a second source/drain structure which is above the first source/drain structure along a first direction;
forming a first conductive segment disposed below the first source/drain structure along the first direction;
forming a second conductive segment disposed above the second source/drain structure along the first direction; and
forming a first via structure and a second via structure coupled to the first conductive segment and the second conductive segment, respectively,
wherein the first via structure is configured to transmit a first reference voltage signal from a first side through the first conductive segment to the first source/drain structure,
the second via structure is configured to transmit a second reference voltage signal from the first side through the second conductive segment to the second source/drain structure, and
the first reference voltage signal and the second reference voltage signal are different from each other.

16. The method of claim 15, wherein the first conductive segment and the second conductive segment comprise a first edge and a second edge, respectively, and
the second via structure is disposed between the first edge and the second edge.

17. The method of claim 16, wherein the second via structure is separated from the second source/drain structure along a second direction different from the first direction, and
the second via structure is disposed between the first edge and the second edge along the second direction.

18. The method of claim 16, further comprising:
forming a third source/drain structure and a fourth source/drain structure which is above the third source/drain structure along the first direction;
forming a third conductive segment disposed below the third source/drain structure along the first direction;
forming a fourth conductive segment disposed above the fourth source/drain structure along the first direction; and
forming a third via structure and a fourth via structure coupled to the third conductive segment and the fourth conductive segment, respectively,
wherein the third via structure is configured to transmit the first reference voltage signal from the first side through the third conductive segment to the third source/drain structure, and
the fourth via structure is configured to transmit the second reference voltage signal from the first side through the fourth conductive segment to the fourth source/drain structure.

19. The method of claim 18, wherein the third conductive segment and the fourth conductive segment comprise a third edge and a fourth edge, respectively, and
the fourth via structure is disposed between the third edge and the fourth edge.

20. The method of claim 18, wherein along the first direction, the fourth via structure has a height larger than a distance between the third conductive segment and the fourth conductive segment, and the second via structure has a height larger than a distance between the first conductive segment and the second conductive segment.
